(19) United States
(12) Patent Application Publication
(10) Pub. No.: US 2009/0174418 A1
(43) Pub. Date: Jul. 9, 2009

(54) Method and Device for Electrically Determining the Thickness of Semiconductor Membranes by Means of an Energy Input

(75) Inventors: Siegfried Hering, Kerspleben (DE); Gisbert Hoelzer, Erfurt (DE)

Correspondence Address: STEVENS & SHOWALTER LLP, 7019 CORPORATE WAY, DAYTON, OH, 45459-4238, US

(73) Assignee: X-FAB Semiconductor Foundries AG, Erfurt (DE)

(21) Appl. No.: 11/577,541

(22) PCT Filed: Oct. 20, 2005
(86) PCT No.: PCT/DE2005/001873

§ 371 Date: Mar. 5, 2009

(30) Foreign Application Priority Data
Oct. 21, 2004 (DE) 10 2004 051 113.6

(51) Int. Cl. G01R 27/08

(52) U.S. Cl. 324/699

(57) ABSTRACT

A method and device for determining the thicknesses of semiconductor membranes uses electrical measurements. Energy is coupled into the membrane in a defined manner and the membrane thickness is determined from the distribution or diffusion of the energy. A change of state of the membrane is detected by measuring electroconductivity of measuring resistances at least one of which is on the membrane. The electroconductivity varies according to the temperature and the mechanical strain of the membrane, which both depend on the thickness of the membrane.

### FIELD OF THE INVENTION

The invention relates to a process and an arrangement for ascertaining the thicknesses of semiconductor membranes.

### BACKGROUND

Components are frequently created in the production of microstructures, which have membranes as sensor faces or covering, the thickness of the membrane being an important parameter for the component behavior and/or further processing steps. The behavior depends decisively on the finally obtained thickness of the membrane in particular for sensor elements, e.g. pressure sensors.

Consequently, the determination of the membrane thickness is an important aspect for controlling the technological production processes and the specification-correct function of a sensor. At present, the membrane thickness is ascertained both by means of destructive processes, e.g. scanning electron microscopy of a vertical fracture through the membrane and non-destructive processes, e.g. optical interferometric processes. Thereafter, the membrane is either destroyed and/or the non-destructive measuring process does not have a sufficient measuring resolution so that essential aspects cannot be determined with the necessary accuracy.

Many processes are known in the field of sensor manufacture in order to change the properties of sensor membranes by means of corresponding treatments in the desired fashion.

A thermal energy input into the membrane for the production of thermally trimmable resistors by means of a targeted change in the electric conductivity of special resistors on the membrane is e.g. known, cf. WO-A 2003/023794.

Also, processes are known for applying thermal energy onto membrane surfaces during use. A thermal energy input into a membrane structure is e.g. used for determining flow rates, the cooling of the membrane being measured by a medium flowing past it, cf. DE-A 197 10 559, DE-A 199 61 129. It is also known to use a thermal energy input into a membrane in order to heat it in a defined fashion and to thus activate chemical reactions for the detection of specific substances—a principle that is e.g. used in gas sensors, cf. DE-B 199 58 311. It is the objective of the energy input to achieve a defined reaction temperature on the membrane.

The mode of action of the membrane pressure sensors is based on the mechanical energy input into the membrane. The membrane is mechanically deformed and the pressure-dependent distortion is customarily capacitively proved, cf. EP-A 195 985, or piezoresistively proved, cf. WO-A 1998/031998, DE-A 197 01 055. The objective of the energy input is the transformation of mechanical into electrical energy through a defined distortion of the membranes Is to measure the applied pressure.

Although there are numerous ways of the treatment of sensor membranes during the actual use and also the manufacture, an efficient and accurate determination of the membrane thickness using non-destructive techniques is not possible at present.

Consequently, the invention is based on the object of designing a non-destructive process and a corresponding device in such a way that thicknesses of semiconductor membranes can be determined with a high degree of accuracy and an expenditure being as little as possible.

### SUMMARY

A process is made available according to the invention, in which a parameter characterizing the thickness of a membrane in a microstructure can be determined by means of electric measurements. Here, energy is input into the membrane in a defined fashion and the membrane thickness is concluded from the distribution/propagation of the energy, by monitoring the changes in the state of the membrane by means of measurements of the electric conductivity by means measuring resistors located on the membrane e.g. in one embodiment. The electric conductivity is changed by the energy input, e.g. in the form of the temperature and the mechanical distortion of the membrane, which both depend on the thickness of the membrane. Suitable reference data can e.g. be used in order to specify the thickness or at least one parameter value that it representative of it. The reference data may also be specified by other measuring processes, e.g. electron microscopy.

Thus, the invention relates to a process and an arrangement for ascertaining the thicknesses of semiconductor membranes by means of electric measurements. Then, energy is input into the membrane in a defined fashion in advantageous embodiments for heating and membrane thickness is inferred from the distribution/propagation of the energy by measuring electric resistivity measuring strips that are applied in a defined fashion after the termination of the energy input in a time-dependent fashion.

The present invention has the advantages that with very little extra expenditure regarding the preparation the membrane thickness on semiconductor wafers and Is on individual finished sensors can be determined in a non-destructive fashion and accurately and rapidly.

Under one aspect of the invention a process for determining the thickness of a membrane in microstructures is moreover made available, the process comprising:

applying a defined energy input onto at least one area of the membrane, obtaining an electric signal from the membrane in reaction to the defined energy input and evaluating the obtained signal for determining at least one parameter representing the thickness of the membrane by means of reference data which describe the dependence of the thickness on the defined energy input.

As stated above, the change in state of a membrane that is caused by an energy input is used according to the invention in order to infer the thickness of the membrane by evaluating the electric signals obtained from the membrane. Since the electric signals can be evaluated in an easy fashion and with great accuracy, an efficient and cost-effective process results, it being possible to also efficiently generate suitable reference data. Data from the electron microscopy of a few samples can e.g. be related to corresponding electric parameters in order to thus be able to obtain an absolute measure for the thickness. Suitable reference data can additionally or alternatively obtained by means of model calculations in other cases.

In a further embodiment the applying a defined energy input onto at least one area of the membrane comprises the heating of at least this area of the membrane.

The heating is a well-tried process for generating temperature gradients and mechanical distortions which depend on the thickness and can thus be used for characterizing the same.

In a further embodiment the heating of the area of the membrane is implemented by means of electric resistance heating elements.

A simple construction of a corresponding structure results from this.

The heating of the area of the membrane takes place by means of laser radiation in a further embodiment, due to which the energy can be input in a very localized fashion.

The signal is obtained and evaluated after the termination of the energy input in a further embodiment

In a further embodiment the signal is evaluated with respect to its change in time after the termination of the energy input. Thus, more information is available, since the subsiding of the increase in temperature over time can e.g. also be used.

In a further embodiment the electric signal includes a reference signal which is obtained from an area adjacent to the area onto which energy is applied and which is substantially not influenced by it. Thus, a difference signal can be obtained which, thus, makes a reduction of interfering influences possible.

In a further embodiment the microstructures are jointly produced on a carrier and the determination of the at least one parameter is carried out prior to the separation of the microstructures. Thus, the obtained information on the membrane thickness can be used for the evaluation of preceding process steps or for the control of subsequent process steps.

In a further embodiment special test fields are provided on the carrier, by means of which at least one parameter is determined. Thus, an efficient product and process monitoring can be implemented without having to carry out essential modifications on the actual products.

In a further embodiment the microstructures are jointly produced on a carrier and the determination of at least one parameter is carried out after the separation of the microstructures. Thus, a determination of the thickness can also be carried out on the finished product so that an increased measure of accuracy in the actual application is possible.

In a further aspect a process for the electric ascertainment of the membrane thickness by means of an energy input is made available. The area of the membrane is heated in a defined fashion and membrane-thickness-dependent changes in the physical states of the membrane that are caused by the heat input are recorded after the termination of the heating as the change over time through corresponding measuring elements which allow the measurement of the changes in the physical states in electrical units. At least one measuring element is located on the membrane and at least one measuring element is located in the non-heated area outside the membrane and the difference of the measuring values of the measuring elements located at different places is used for ascertaining the membrane thickness.

Further advantageous developments are indicated in the dependent claims and in the following detailed description.

### OVERVIEW DRAWING

The invention will be described and supplemented by means of examples with the aid of the drawing.

FIG. 1 schematically shows a measuring arrangement consisting of a membrane 1 with a surrounding area as a cutout of a semiconductor wafer 10. Heat distribution and mechanical distortion of the membrane depend on the membrane thickness “h” with the heating performance being known and are electrically measured through corresponding measuring strips.

### DESCRIPTION OF EMBODIMENTS

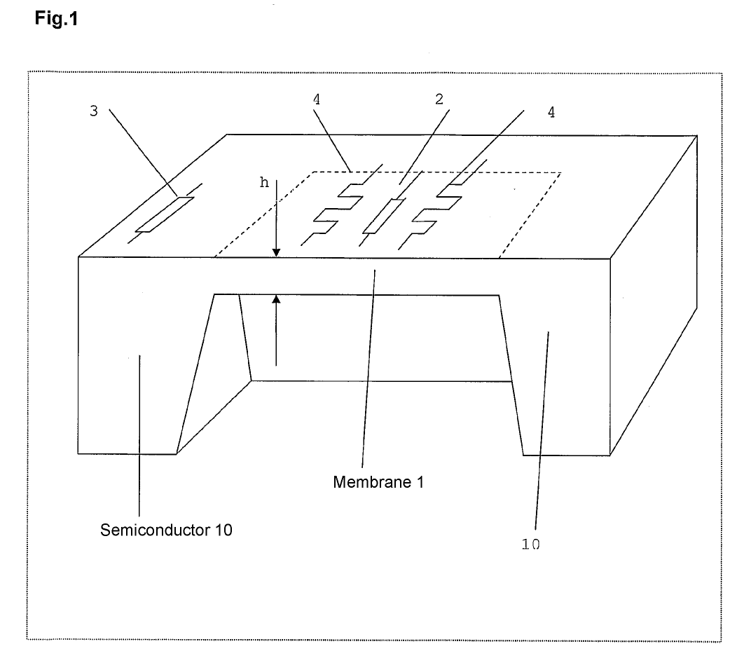

In FIG. 1 the input of the electric energy into the semiconductor membrane 1 having a microstructure 10 is carried out by means of a large-surface heater arrangement with electric resistance heating elements 4 on the membrane 1. The electric measuring resistor 2 disposed between the electric resistance heating elements 4 and the electrical measuring resistor 3 is disposed in the non heated marginal area of the membrane as a component of an electric bridge circuit (not shown) serve for measuring.

In one embodiment the process is based on the evaluation of the changes in resistance of the measuring resistor 2 located on the heated membrane 1 after a specific time, that are caused by a change in the thickness-depending mechanical distortion and heat conductance in the membrane after the termination of the energy input.

One embodiment relates to a measuring arrangement for the electric ascertainment of the membrane thickness by means of energy input, means 4 being present on the membrane 1, which heat the area of the membrane 1 in a defined fashion, and at least one measuring element 2 being located on the membrane and at least one measuring element 3 being located in the non-heated area outside the membrane 1, which allow the measuring detection by means of membrane-thickness-dependent time changes in physical states of the membrane 1, which are caused by and after the heat input, the indirectly through electrical units and measuring means, e.g. in the form of known measuring means, are present, which ascertain the membrane thickness from the changing difference of the measuring values of the measuring elements 2, 3 located at the different locations as compared with the energy input.

In a further embodiment the means 4 for heating the membrane 1 consists of electric resistance heating elements.

In a further embodiment the means 4 for heating the membrane 1 consists of two electric resistance heating elements that are symmetrically positioned at both sides of the measuring element 2 on the membrane 1.

In a further embodiment the measuring means detecting the difference of the measuring values of the measuring elements 2 on the membrane 1 and outside of the membrane 1 is a bridge circuit.

In a further embodiment the heating and measuring elements formed on the semiconductor wafer are a component of special test fields.

In a further embodiment the heating and measuring elements formed on the semiconductor wafer are a component of a finished sensor.

In a further embodiment the heating and measuring elements formed on the semiconductor wafer together with the integrated measuring bridge circuit are a component of special test fields.

In a further embodiment the heating and measuring elements formed on the semiconductor wafer 10 together with the integrated measuring bridge circuit are a component of the finished sensor.

### REFERENCE NUMERALS

1 Membrane as a component of a semiconductor body 10
2 Electric measuring resistor
3 Electric comparative measuring resistor
4 Electric resistance heating element
h Membrane thickness

1. A process for determining a thickness of a membrane in a microstructure:
applying a defined or set metered energy input of a first magnitude onto at least one area of said membrane;
obtaining an electric signal from said membrane in reaction or response to said energy input; and
evaluating said obtained electric signal for determining at least one parameter representing the thickness of the membrane by means of reference data which depict the dependence of the thickness as a function of said energy input.

2. The process according to claim 1, wherein applying said metered energy input onto at least one area of said membrane comprises heating said at least one area of said membrane.

3. The process according to claim 2, wherein said heating of said at least one area of said membrane is carried out by means of electric resistance heating elements.

4. The process according to claim 1, wherein microstructures are jointly produced on a carrier and said determination of the at least one parameter is carried out after separation of said microstructures.

5. The process according to claim 1, wherein applying said metered energy input onto at least one area of said membrane comprises heating said at least one area of said membrane by means of laser radiation.

6. The process according to claim 1, wherein said electric signal is obtained and evaluated after termination of said energy input.

7. The process according to claim 6, wherein said electric signal is evaluated in view of its change over time after the termination of said energy input.

8. The process according to claim 1, wherein said electric signal includes a reference signal which is obtained from an area adjacent to said area onto which energy is applied, said adjacent area being substantially not influenced by said energy input.

9. The process according to claim 1, wherein microstructures are jointly produced on a carrier and said determination of the at least one parameter is carried out prior to separation of said microstructures.

10. The process according to claim 9, wherein special test fields are provided on said carrier, at which at least one parameter is determined.

11. The process according to claim 1, wherein applying a metered energy input comprises applying mechanical energy.

12. The process according to claim 1, wherein changing energy physical states produced by applying a metered energy input are:
elastic mechanical tension and
temperature which impact electrical measuring strips elements so that associated time changes of electrical resistivity of said electrical measuring strips can be elements measured.

13. A process for the electric ascertainment of a membrane thickness by means of an energy input, wherein
an area of the membrane is heated in a defined fashion and membrane-thickness-dependent changes in the physical states of the membrane, which are caused by the energy input, are recorded or detected after a termination of the heating as an energy of input in the change over time through measuring elements detecting the change, which allow the measuring of the changes in the physical states in electrical signals; and
at least one measuring element is located on the membrane and at least one measuring element is located in a non-heated area outside the membrane and the difference in the measuring values of the measuring elements on the membrane and outside the membrane are used for ascertaining the membrane thickness.

14. The process according to claim 13, wherein the physical states which are changed by said energy input are the elastic mechanical tension and the temperature and wherein electric resistivity strips serve as measuring elements for detecting time changes.

15. The process according to claim 13, wherein heating of said area of said membrane is carried out by means of electric resistance heating elements.

16. The process according to claim 13, wherein heating of said area of said membrane is performed by means of laser radiation.
